(19) United States
(12) Patent Application Publication
(10) Pub. No.: US 2007/0096773 A1
(43) Pub. Date: May 3, 2007

(54) Sample and hold circuit with multiple channel inputs, and analog-digital converter incorporating the same

(76) Inventors: Hajime Takashima, Anpachi-Gun (JP); Shigeto Kobayashi, Anpachi-Gun (JP); Atsushi Wada, Ogaki-shi (JP)

Correspondence Address: MCDERMOTT WILL & EMERY LLP, 600 13TH STREET, N.W., WASHINGTON, DC, 20005-3096, US

(21) Appl. No.: 11/590,003

(22) Filed: Oct. 31, 2006

(30) Foreign Application Priority Data
Oct. 31, 2005 (JP) 2005-315793
Oct. 25, 2006 (JP) 2006-290481

(51) Int. Cl. G11C 27/02

(52) U.S. Cl. 327/94

(57) ABSTRACT

It is required to provide a further reduction in circuit scale to perform time division sampling and holding using a plurality of sampling capacitors and a common operational amplifier. The plurality of sampling capacitors sample input analog signals of multiple channels on each channel. Switches are provided corresponding in number to the sampling capacitors to selectively output a voltage sampled at one terminal of each of the sampling capacitors from the other terminal to the operational amplifier. A feedback capacitor is provided in a feedback path that connects between the input terminal and the output terminal of the operational amplifier. An S&H circuit performs time division sampling and holding by the switches being selectively turned ON.

### BACKGROUND OF THE INVENTION

1. Field of the Invention

The present invention relates to a sample and hold circuit for performing time division sampling and holding on input analog signals of multiple channels with a common operational amplifier, and to an analog-digital converter incorporating the sample and hold circuit.

2. Description of the Related Art

A sample and hold circuit (hereinafter referred to as an S&H circuit as appropriate) is a circuit which samples the voltage of an analog signal at a given point in time and holds the voltage at that given point. When an analog-to-digital conversion (hereinafter referred to as an AD conversion as appropriate) is performed on a time-varying signal, the S&H circuit is often used to provide the input voltage to an AD converter.

A technique for reducing the size of an S&H circuit has been disclosed in which the S&H circuit is provided with a plurality of sampling portions and a common holding portion to sample and hold time division input signals (e.g., see FIG. 1 of Japanese Patent Laid-Open Publication No. 2004-158138). One variation of an S&H circuit is also known as a switched capacitive operational amplifier in which the input terminal is provided with serial sampling capacitors (e.g., see FIG. 17 of Japanese Patent Laid-Open Publication No. 2004-158138).

[Patent Document 2] Japanese Patent Laid-Open Publication No. Hei 8-125495

As shown in FIG. 1 of Japanese Patent Laid-Open Publication No. 2004-158138, the S&H circuit with the plurality of sampling portions and the common holding portion can sample and hold input signals from multiple channels as well as provide a reduced circuit scale when compared to an S&H circuit having no common holding portion. The inventor has developed a technique for further reducing the circuit scale of such an S&H circuit.

### SUMMARY OF THE INVENTION

The present invention was developed in response to the aforementioned circumstances. It is therefore a general purpose of the invention to provide a sample and hold circuit where the circuit scale is reduced but remains compatible with multiple channel inputs.

To address the aforementioned challenge, a sample and hold circuit according to an embodiment of the present invention includes one operational amplifier; one feed back capacitor located in a feedback path connecting an input terminal and an output terminal of the operational amplifier; a plurality of sampling capacitors which sample input analog signals of multiple channels on each channel; and switches which selectively supply voltages sampled at one terminal of the plurality of sampling capacitors from the other terminal to the operational amplifier, the switches corresponding in number to the capacitors. In the sample and hold circuit, the switches are selectively turned ON, thereby performing time division sampling and holding.

According to this embodiment, the feed back capacitor is shared among the plurality of channels, thereby allowing the sample and hold circuit scale to be reduced but still remain compatible with multiple channel inputs.

Another embodiment of the present invention is also a sample and hold circuit. This sample and hold circuit includes one operational amplifier; a plurality of sampling capacitors which sample input analog signals of multiple channels on each channel; first switches which selectively supply voltages sampled at one terminal of the plurality of sampling capacitors from the other terminal to the operational amplifier, the first switches corresponding in number to the capacitors; and an auto-zero voltage generation circuit which applies a voltage to the other terminal of a sampling capacitor during a sampling period, the voltage corresponding to an input node voltage of the operational amplifier in an auto-zero state. The sample and hold circuit selectively turns ON the first switches, thereby performing time division sampling and holding.

According to this embodiment, the sample and hold circuit scale can be reduced but still remain compatible with multiple channel inputs. Additionally, even when a sampling capacitor and the operational amplifier are not connected to each other, such a condition can be virtually created in which the other terminal of a sampling capacitor during a sampling period is connected to the operational amplifier in an auto-zero state. It is thus possible to prevent degradation in the accuracy of a sampling voltage in the case where analog signals of multiple channels are being sampled.

Second switches which correspond in number to the sampling capacitors may also be provided between the other terminals of the sampling capacitors and the auto-zero voltage generation circuit. The size of the first switches and the size of the second switches may correspond to each other on each channel. According to this embodiment, such feedthrough noise that occurs when a second switch is turned OFF can be canceled when a first switch is turned ON, thereby preventing the effects of noise.

The auto-zero voltage generation circuit may be controlled in a standby mode, as appropriate, within a period of time during which all the first switches are turned OFF and then turned ON. Alternatively, the auto-zero voltage generation circuit may also be controlled in a standby mode or power saving mode at least during part of a period of time in which all the second switches are in an OFF state. According to this embodiment, it is possible to reduce power consumption of the auto-zero voltage generation circuit.

The auto-zero voltage generation circuit may be a dedicated circuit for generating an auto-zero voltage. Alternatively, the auto-zero voltage generation circuit may also be a self-bias voltage generation circuit in the operational amplifier or in another operational amplifier. Use of a self-bias voltage generation circuit in the operational amplifier or in another operational amplifier would make it possible to prevent an increase in circuit scale.

Another embodiment of the present invention is an analog-digital converter. The analog-digital converter incorporates the sample and hold circuit according to the aforementioned embodiment. The sample and hold circuit may also be applied to a circuit for sampling an input analog signal to an AD converter. In the case of a method for performing separate multiple-time conversions of an analog signal into a digital signal, the sample and hold circuit may also be applied to a circuit which subtracts an analog value obtained by a digital-to-analog conversion of a converted output digital value from a sampled and held analog value and then amplifies the resulting analog value. The sample and hold circuit may also be applied to a circuit which selectively samples an input analog signal from the upstream stage and a feedback input analog signal from its own stage.

According to this embodiment, it is also possible to prevent an increase in circuit scale for entire analog-to-digital conversion.

Note that any combination of the aforementioned components or a representation of the present invention exchanged between methods, apparatuses, or systems will also be considered to be effective as an embodiment of the present invention.

### BRIEF DESCRIPTION OF THE DRAWINGS

Embodiments will now be described, by way of example only, with reference to the accompanying drawings which are meant to be exemplary, not limiting, and wherein like elements are numbered alike in several Figures, in which:

FIG. 1 is a view illustrating the configuration of an S&H circuit according to a first embodiment of the present invention;

FIG. 2 is a view illustrating the internal configuration of an operational amplifier according to a first example;

FIG. 3 is a view illustrating the internal configuration of an operational amplifier according to a second example;

FIG. 4 is a view illustrating an example in which an external auto-zero voltage supply operational amplifier is employed as an external auto-zero voltage generation circuit;

FIG. 5 is an explanatory view illustrating an exemplary detailed operation of the S&H circuit according to the first embodiment;

FIG. 6 is a view illustrating an exemplary configuration of an AD converter incorporating an S&H circuit;

FIG. 7 is a view illustrating the configuration of an S&H circuit according to a second embodiment of the present invention; and

FIG. 8 is a view illustrating the configuration of an S&H circuit according to a third embodiment of the present invention.

### DETAILED DESCRIPTION OF THE INVENTION

The invention will now be described by reference to the preferred embodiments. This does not intend to limit the scope of the present invention, but to exemplify the invention.

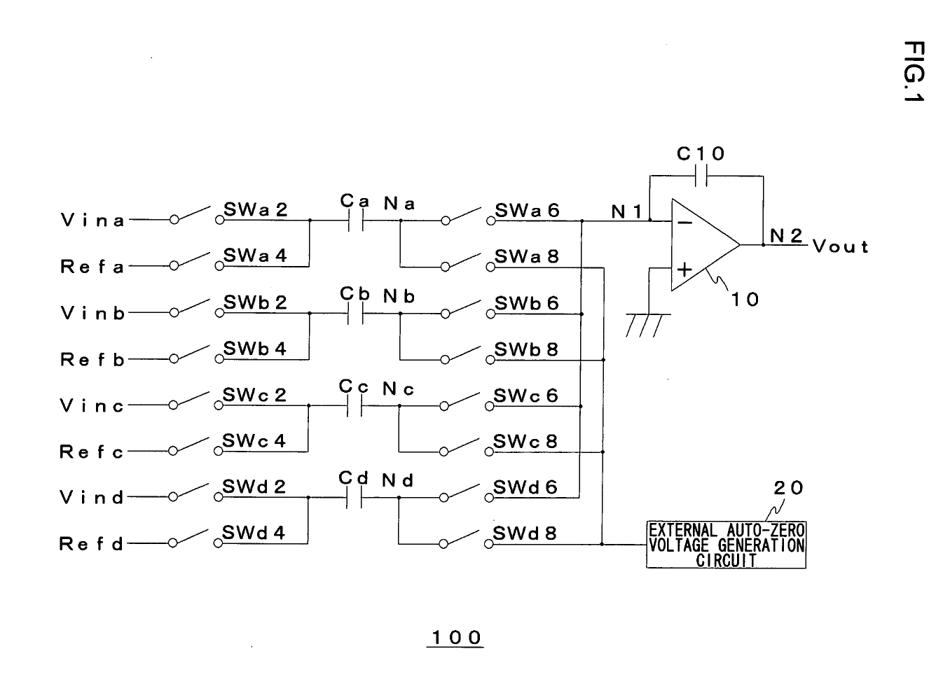

FIG. 1 shows the configuration of an S&H circuit 100 in accordance with a first embodiment of the present invention. The S&H circuit 100 has a single-end switched capacitive type configuration with four channel inputs. The four channel input analog voltages Vina, Vinb, Vinc, and Vind are applied to corresponding electrodes of an Ach sampling capacitor Ca, a Bch sampling capacitor Cb, a Cch sampling capacitor Cc, and a Dch sampling capacitor Cd via an Ach first switch SWa2, a Bch first switch SWb2, a Cch first switch SWc2, and a Dch first switch SWd2, respectively. The reference voltages Refa, Refb, Refc, and Refd are also applied to the aforementioned corresponding electrodes of the Ach sampling capacitor Ca, the Bch sampling capacitor Cb, the Cch sampling capacitor Cc, and the Dch sampling capacitor Cd via an Ach second switch SWa4, a Bch second switch SWb4, a Cch second switch SWc4, and a Dch second switch SWd4, respectively.

The other electrodes of the Ach sampling capacitor Ca, the Bch sampling capacitor Cb, the Cch sampling capacitor Cc, and the Dch sampling capacitor Cd are connected to the inverting input terminals of an operational amplifier 10 via an Ach third switch SWa6, a Bch third switch SWb6, a Cch third switch SWc6, and a Dch third switch SWd6, respectively. Additionally, the electrodes of the Ach sampling capacitor Ca, the Bch sampling capacitor Cb, the Cch sampling capacitor Cc, and the Dch sampling capacitor Cd are also connected to an external auto-zero voltage generation circuit 20 via an Ach fourth switch SWa8, a Bch fourth switch SWb8, a Cch fourth switch SWc8, and a Dch fourth switch SWd8, respectively. The sizes of the Ach third switch SWa6, the Bch third switch SWb6, the Cch third switch SWc6, and the Dch third switch SWd6 are designed to be substantially equal to the sizes of the Ach fourth switch SWa8, the Bch fourth switch SWb8, the Cch fourth switch SWc8, and the Dch fourth switch SWd8, respectively.

The non-inverting input terminal of the operational amplifier 10 is grounded. The output terminal and the inverting input terminal of the operational amplifier 10 are connected to each other via a feedback capacitor C10. The external auto-zero voltage generation circuit 20 generates a voltage which is substantially equal to the auto-zero voltage of the operational amplifier 10, and functions as a replica circuit of the operational amplifier 10. Note that FIG. 1 shows an example in which all the channels share one external auto-zero voltage generation circuit 20. However, the external auto-zero voltage generation circuit 20 may also be provided as one circuit for each channel, or alternatively, the external auto-zero voltage generation circuit 20 may be provided as one circuit for a plurality of channels, for example, two channels.

A description will be now provided regarding the basic operation of the S&H circuit 100 in accordance with the first embodiment. By way of example, the operation of the A-channel will be described below. To sample an input analog voltage Vina of the A-channel, the Ach first switch SWa2 is turned ON, and the Ach second switch SWa4 is turned OFF. Then, since the Ach third switch SWa6 is in an ON state when the A-channel has been selected, an auto-zero voltage is applied from inside the operational amplifier 10 to an electrode of the Ach sampling capacitor Ca on the operational amplifier 10 side. Thus, the Ach fourth switch SWa8 is in an OFF state without the need for external application of the auto-zero voltage.

In contrast to this, since the Ach third switch SWa6 is in an OFF state when the A-channel is not selected, the auto-zero voltage is not applied from inside the operational amplifier 10 to the electrode of the Ach-sampling capacitor Ca. Thus, the Ach fourth switch SWa8 is in an ON state, requiring external application of the auto-zero voltage.

Next, to hold or amplify the voltage value that has been sampled by the S&H circuit 100, the Ach first switch SWa2 is turned OFF, and the Ach second switch SWa4 is turned ON. Then, the Ach third switch SWa6 is turned ON, and the Ach fourth switch SWa8 is turned OFF. This allows the operational amplifier 10 to amplify the sampled voltage value.

A description will now be provided regarding the principle on which the S&H circuit 100 bases for holding or amplification. The charge QA on an input side node N1 of the operational amplifier 10 is expressed by the following equation (A1) during an auto-zero period.
QA=Ca(Vina−Vag) . . . (A1)
where Ca represents the capacitance value of the capacitor Ca, and Vag represents the auto-zero voltage of the operational amplifier 10.

On the other hand, the charge QB on the input side node N1 is expressed by the following equation (A2) during an amplification period. During this period, the input side node N1 is virtually grounded.
QB=Ca(Refa−Vag)+C10(Vout−Vag) . . . (A2)
where Refa represents the reference voltage of the A-channel, and C10 represents the capacitance value of the feedback capacitor C10.

Since the input side node N1 has no path for the charge to escape therethrough, the principle of conservation of charge tells that QA=QB, and the following equation (A3) holds.
Vout=Ca/C10(Vina−Refa)+Vag . . . (A3)

It is thus possible to hold the input analog voltage Vina by making the capacitance values of the Ach sampling capacitor Ca and the feedback capacitor C10 equal to each other as well as by making the reference voltage Refa and the auto-zero voltage Vag equal to each other. Alternatively, each parameter can also be adjusted for amplification.

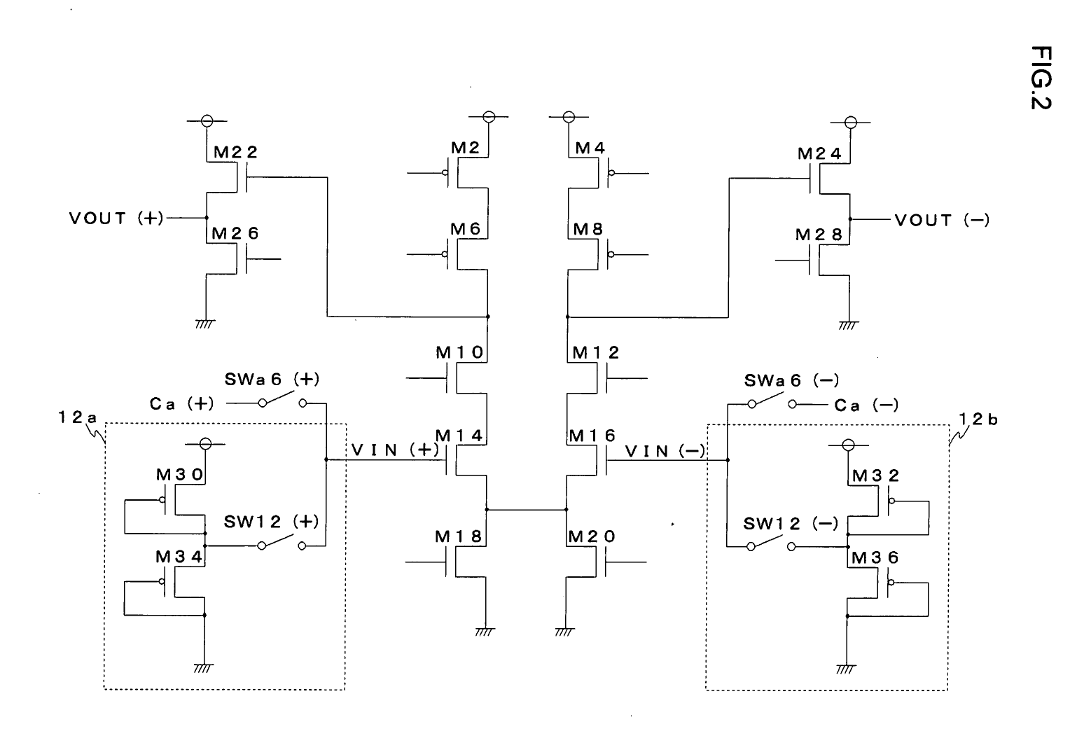

FIG. 2 shows a first example of the internal configuration of the operational amplifier 10. For the sake of simplicity, FIG. 1 shows an example of a single-end method. Now, with reference to FIG. 2, a description will be provided of an exemplary internal configuration of a fully differential method. When compared with the single-end method, the fully differential method provides good resistance to noise and increased output amplitude. FIG. 2 shows an operational amplifier 10 that is formed by the CMOS (Complementary Metal-Oxide Semiconductor) process. Hereinafter, the P channel-type MOS (Metal-Oxide Semiconductor) field effect transistor will be referred to as the PMOS transistor, while the N channel-type MOS field effect transistor will be referred to as the NMOS transistor.

A pair of a first PMOS transistor M2 and a second PMOS transistor M4 is supplied with a supply voltage Vdd at their source electrodes and with a predetermined bias voltage at their gate electrodes. A pair of a third PMOS transistor M6 and a fourth PMOS transistor M8 is supplied with a predetermined bias voltage at their gate electrodes, and their source electrodes are connected to the drain electrodes of the first PMOS transistor M2 and the second PMOS transistor M4, respectively. A pair of a first NMOS transistor M10 and a second NMOS transistor M12 is supplied with a predetermined bias voltage at their gate electrodes, and their drain electrodes are connected to the drain electrodes of the third PMOS transistor M6 and the fourth PMOS transistor M8, respectively.

The gate electrodes of a pair of a third NMOS transistor M14 and a fourth NMOS transistor M16 are connected to the “+” side and “−” side input terminals of the operational amplifier 10, respectively, while their drain electrodes are connected to the source electrodes of the first NMOS transistor M10 and the second NMOS transistor M12, respectively. The pair of the third NMOS transistor M14 and the fourth NMOS transistor M16 forms a differential pair. A circuit configured as such is generally referred to as a cascode amplifier or cascode operational amplifier. A pair of a fifth NMOS transistor M18 and a sixth NMOS transistor M20 is supplied with a predetermined bias voltage at their gate electrodes with their source electrodes connected to the ground, while their drain electrodes are connected to the source electrodes of the third NMOS transistor M14 and the fourth NMOS transistor M16, respectively. The pair of the fifth NMOS transistor M18 and the sixth NMOS transistor M20 functions as a constant-current power supply.

The voltage at a point of connection between the third PMOS transistor M6 and the first NMOS transistor M10 is applied to the gate electrode of a seventh NMOS transistor M22, while the voltage at a point of connection between the fourth PMOS transistor M8 and the second NMOS transistor M12 is applied to the gate electrode of an eighth NMOS transistor M24. The seventh NMOS transistor M22 and a ninth NMOS transistor M26 form a source follower with its output voltage employed as a “+” side output voltage VOUT (+). The eighth NMOS transistor M24 and a tenth NMOS transistor M28 also form a source follower with its output voltage employed as a “−” side output voltage VOUT (−).

An internal auto-zero voltage generation circuit 12 generates an auto-zero voltage which is applied to one electrode of each of the A to Dch sampling capacitors Ca to Cd and the feedback capacitor C10. In FIG. 2, a first potential divider circuit having a fifth PMOS transistor M30 and a seventh PMOS transistor M34 connected in series, and a second potential divider circuit having a sixth PMOS transistor M32 and an eighth PMOS transistor M36 connected in series are used to generate the “+” side and “−” side auto-zero voltages. It should be appreciated that the potential divider circuits may also be made up of resistors and other components. The “+” side auto-zero voltage is applied to the “+” side input terminal of the operational amplifier 10 via a first auto-zero switch SW12 (+), while the “−” side auto-zero voltage is applied to the “−” side input terminal of the operational amplifier 10 via a first auto-zero switch SW12 (−)

Note that instead of the external auto-zero voltage generation circuit 20, the output from the internal auto-zero voltage generation circuit 12 may also be connected through a different path to the Ach fourth switch SWa8, the Bch fourth switch SWb8, the Cch fourth switch SWc8, and the Dch fourth switch SWd8. In this case, it is not necessary to provide the external auto-zero voltage generation circuit 20 separately.

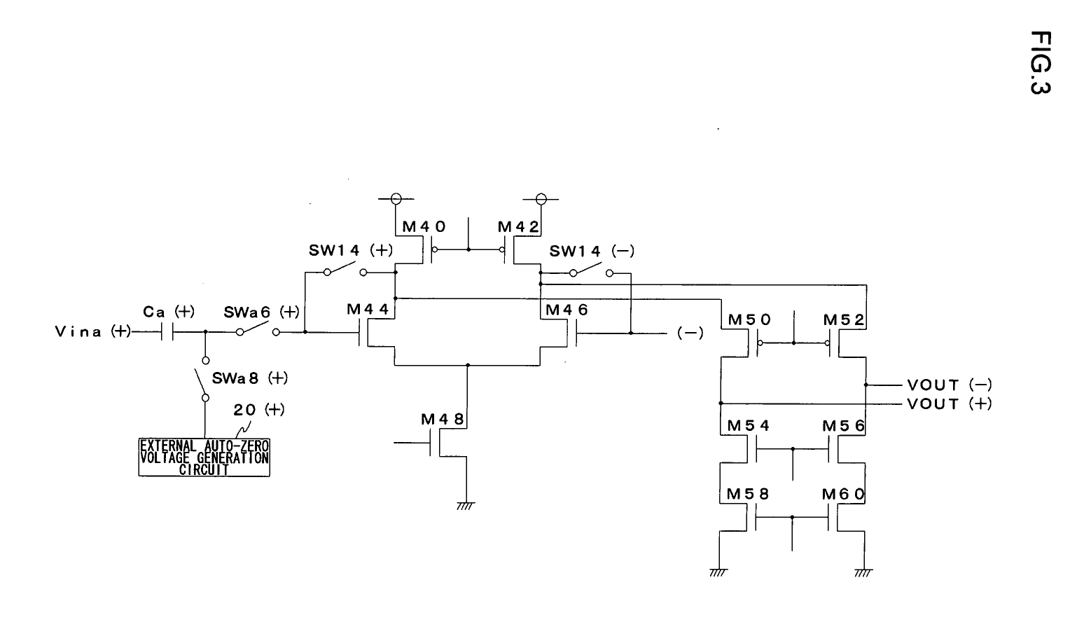

FIG. 3 shows a second example of the internal configuration of an operational amplifier 10. The operational amplifier 10 can use a self-bias voltage to adjust an auto-zero voltage value.

A pair of a ninth PMOS transistor M40 and a tenth PMOS transistor M42 is supplied with the supply voltage Vdd at their source electrodes, and their gate electrodes are supplied with a predetermined bias voltage. The gate electrodes of a pair of an 11th NMOS transistor M44 and a 12th NMOS transistor M46 are connected to the “+” side and “−” side input terminals of the operational amplifier 10, respectively, while their drain electrodes are connected to the drain electrodes of the ninth PMOS transistor M40 and the tenth PMOS transistor M42, respectively. The source electrodes of the pair of the 11th NMOS transistor M44 and the 12th NMOS transistor M46 are connected in common to the drain electrode of a 13th NMOS transistor M48. The 13th NMOS transistor M48 is supplied with a predetermined bias voltage at its gate electrode with its source electrode connected to the ground. The 13th NMOS transistor M48 functions as a constant-current power supply.

A point of connection between the ninth PMOS transistor M40 and the 11th NMOS transistor M44 is connected to the “+” side input terminal of the operational amplifier 10 via a second auto-zero switch SW14 (+). Likewise, a point of connection between the tenth PMOS transistor M42 and the 12th NMOS transistor M46 is connected to the “−” side input terminal of the operational amplifier 10 via a second auto-zero switch SW14 (−). The auto-zero voltage can be generated by turning ON the second auto-zero switch SW14 during an auto-zero period. The bias voltage applied to the gate electrodes of the ninth PMOS transistor M40 and the tenth PMOS transistor M42 can be used to adjust the auto-zero voltage. These configurations function in the same manner as the internal auto-zero voltage generation circuit 12 described above.

Additionally, the voltage at a point of connection between the ninth PMOS transistor M40 and the 11th NMOS transistor M44 is applied to the source electrode of an 11th PMOS transistor M50, while the voltage at a point of connection between the tenth PMOS transistor M42 and the 12th NMOS transistor M46 is applied to the source electrode of a 12th PMOS transistor M52.

A predetermined bias voltage is applied to the pair of the 11th PMOS transistor M50 and the 12th PMOS transistor M52 at their gate electrodes. A pair of a 14th NMOS transistor M54 and a 15th NMOS transistor M56 is supplied with a predetermined bias voltage at their gate electrodes, while their drain electrodes are connected to the drain electrodes of the 11th PMOS transistor M50 and the 12th PMOS transistor M52, respectively. A pair of a 16th NMOS transistor M58 and a 17th NMOS transistor M60 is supplied with a predetermined bias voltage at their gate electrodes with their drain electrodes connected to the source electrodes of the 14th NMOS transistor M54 and the 15th NMOS transistor M56, respectively, and their source electrodes are connected to the ground. The 16th NMOS transistor M58 and the 17th NMOS transistor M60 act as a constant-current power supply.

The voltage at a point of connection between the 11th PMOS transistor M50 and the 14th NMOS transistor M54 is employed as the “+” side output voltage VOUT (+), while the voltage at a point of connection between the 12th PMOS transistor M52 and the 15th NMOS transistor M56 is employed as the “−” side output voltage VOUT (−). It is possible to use a replica circuit of the operational amplifier 10 as the external auto-zero voltage generation circuit 20, according to the second example. The replica circuit to be used may be one which is, for example, the same in size as the operational amplifier 10, or a full-scale or one half replica thereof.

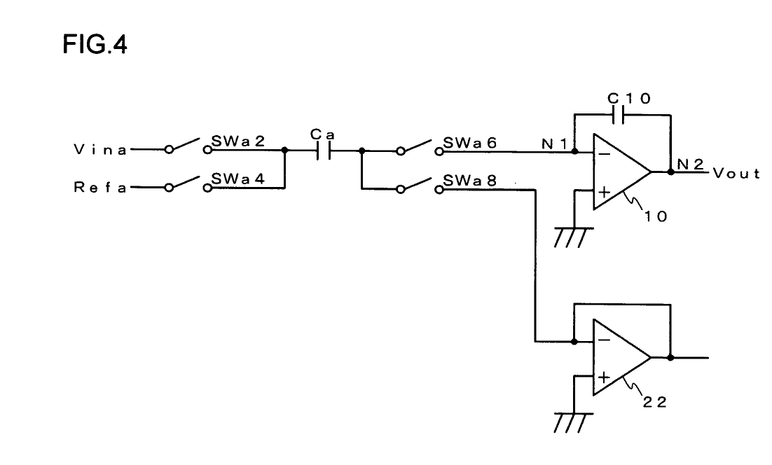

A description will now be provided regarding an example in which another operational amplifier is used as an example of the external auto-zero voltage generation circuit 20. FIG. 4 is a view showing an example in which an external auto-zero voltage supply operational amplifier 22 is used as the external auto-zero voltage generation circuit 20. When a plurality of operational amplifiers which are less in number than the multiple channels are used for sampling and holding the inputs of the multiple channels, the external auto-zero voltage generation circuit 20 corresponds to an operational amplifier in an auto-zero state. On the other hand, the external auto-zero voltage generation circuit 20 also corresponds to another operational amplifier residing on the same semiconductor substrate. These operational amplifiers need to be capable of generating an auto-zero voltage in such a configuration as discussed in FIGS. 2 and 3.

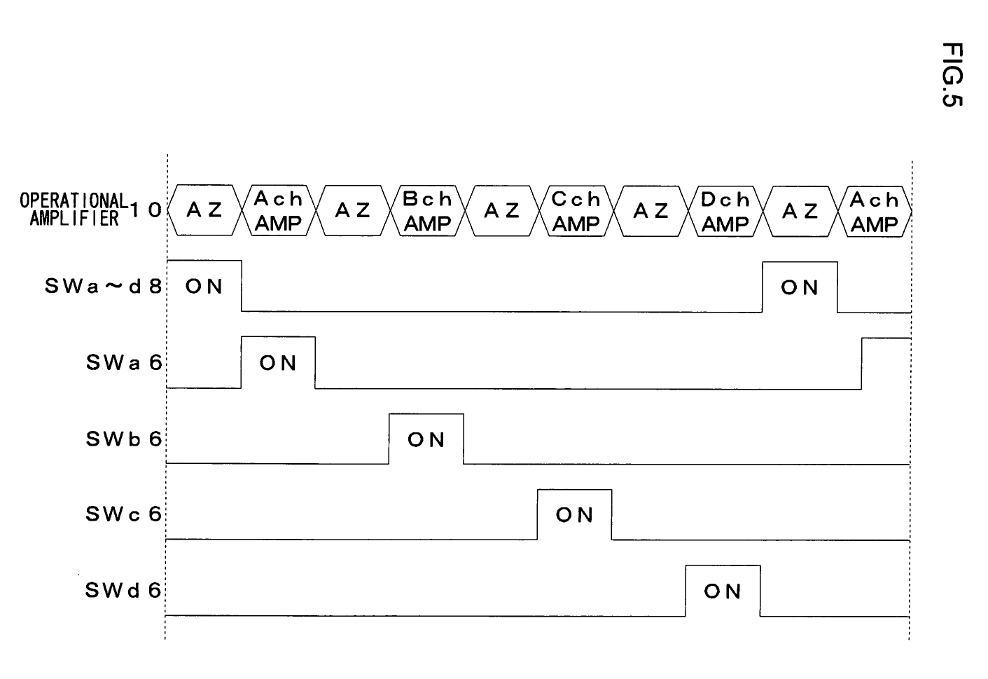

FIG. 5 is an explanatory view showing a detailed example of the operation of the S&H circuit 100 in accordance with the first embodiment. Now, with reference to FIG. 5, a description will be provided regarding the example of the operation of the S&H circuit 100 configured as shown in FIG. 1. First, the S&H circuit 100 samples the input analog voltages Vina to Vind. The sampling may be performed simultaneously. In a state during sampling of input analog voltages (hereinafter referred to as status 1), the Ach second switch SWa4, the Bch second switch SWb4, the Cch second switch SWc4, and the Dch second switch SWd4 are in an OFF state, whereas the Ach first switch SWa2, the Bch first switch SWb2, the Cch first switch SWc2, and the Dch first switch SWd2 are turned ON. On the other hand, the Ach third switch SWa6, the Bch third switch SWb6, the Cch third switch SWc6, and the Dch third switch SWd6 are in an OFF state, whereas the Ach fourth switch SWa8, the Bch fourth switch SWb8, the Cch fourth switch SWc8, and the Dch fourth switch SWd8 are turned ON. The operational amplifier 10 is in an auto-zero state.

Then, the S&H circuit 100 ends the sampling of the input analog voltages Vina to Vind. When the sampling is ended (hereinafter referred to as status 2), the Ach first switch SWa2, the Bch first switch SWb2, the Cch first switch SWc2, and the Dch first switch SWd2 are turned OFF, whereas the Ach fourth switch SWa8, the Bch fourth switch SWb8, the Cch fourth switch SWc8, and the Dch fourth switch SWd8 are turned OFF. The operational amplifier 10 is in an auto-zero state.

Next, the S&H circuit 100 starts to hold or amplify the input analog voltage Vina of the selected channel (In this instance it is assumed that the A-channel is selected). At the start of the operation (hereinafter referred to as status 3), the Ach second switch SWa4 is turned ON and the Ach third switch SWa6 is turned ON. The operational amplifier 10 is activated. Those channels that were not selected (here, the B to D channels) remain in the circuit state of status 2.

Then, the S&H circuit 100 ends the holding or amplifying of the input analog voltage Vina of the channel. At the end of the operation (hereinafter referred to as a status 4), the Ach second switch SWa4 is turned OFF and the Ach third switch SWa6 is also turned OFF. The operational amplifier 10 is driven into an auto-zero state, ready for the next operation of amplification.

Status 1 and status 2 are maintained at the same time for the four channels, whereas status 3 and status 4 are time multiplexed on each channel. Since the S&H circuit 100 has four channels, its one sampling allows such a circuit state transition to take place as status 1, status 2, status 3, status 4, status 3, status 4, status 3, status 4, status 3, and status 4 in that order.

FIG. 5 shows a timing chart of the circuit state transition. As shown in FIG. 5, the Ach fourth switch SWa8, the Bch fourth switch SWb8, the Cch fourth switch SWc8, and the Dch fourth switch SWd8 are in an ON state during status 1. The switches are in an OFF state during status 2, status 3, and status 4. The larger the number of channels, i.e., the greater the number of times the repetition of status 3 and status 4, the longer the OFF periods of the Ach fourth switch SWa8, the Bch fourth switch SWb8, the Cch fourth switch SWc8, and the Dch fourth switch SWd8 become. During this OFF period, the external auto-zero voltage generation circuit 20 is driven into a standby mode. That is, during the period from the first status 3 to the last status 3 in one cycle, the external auto-zero voltage generation circuit 20 is maintained in a standby mode. This makes it possible to reduce the power consumption of the external auto-zero voltage generation circuit 20. The larger the number of channels, the greater the effect of reducing the power consumption becomes. Note that the external auto-zero voltage generation circuit 20 may also be transitioned into a power saving mode rather than being driven into a standby mode.

As described above, this embodiment provides an S&H circuit which employs the plurality of sampling capacitors and the common operational amplifier to perform time division sampling and holding, thereby achieving a reduction in circuit scale by sharing the feedback capacitor C10 in addition to the sharing of the operational amplifier 10. It is also possible to provide the same value to the feedback capacitor of each channel, thereby preventing a signal difference between the channels. That is, each of the feedback capacitors provided for one channel would cause a relative signal difference between the channels due to variations in the properties of the feedback capacitors in addition to variations in the properties of the sampling capacitors. However, this embodiment can eliminate the effects of variations in the properties of the feedback capacitors. Furthermore, the auto-zero voltage generation circuit is also provided separately in addition to the operational amplifier. Even during the process of one channel input signal being amplified by the operational amplifier, this configuration allows an auto-zero voltage to be applied to the sampling capacitor of another channel, thereby making it possible to sample the input signal of that channel. That is, the sampling timing of each channel can be arbitrarily set. Furthermore, without being connected to the operational amplifier, the operational amplifier side electrode of the sampling capacitor of a channel in a sampling period can be virtually maintained in the same state as it is connected to the operational amplifier. Accordingly, when compared with a typical S&H circuit which receives a single input without time division, the S&H circuit according to this embodiment can prevent degradation in the accuracy of the sampling voltages generated.

On the other hand, the configuration of the first embodiment may cause feedthrough noise to occur. For example, in the A-channel, feedthrough noise is added to a node Na when the Ach fourth switch SWa8 is turned OFF. In this respect, the Ach third switch SWa6 and the Ach fourth switch SWa8 may be made substantially equal in size. This allows for the drawing of the amount of charges corresponding to the feedthrough noise from the node Na when the Ach third switch SWa6 is subsequently turned ON. In other words, the Ach third switch SWa6 has absorbed the feedthrough noise. This holds true for the other channels. Accordingly, when a plurality of sampling capacitors and a common operational amplifier are used to perform time division sampling and holding, it is possible to reduce the effects of feedthrough noise, thereby preventing degradation in accuracy of sampling voltages.

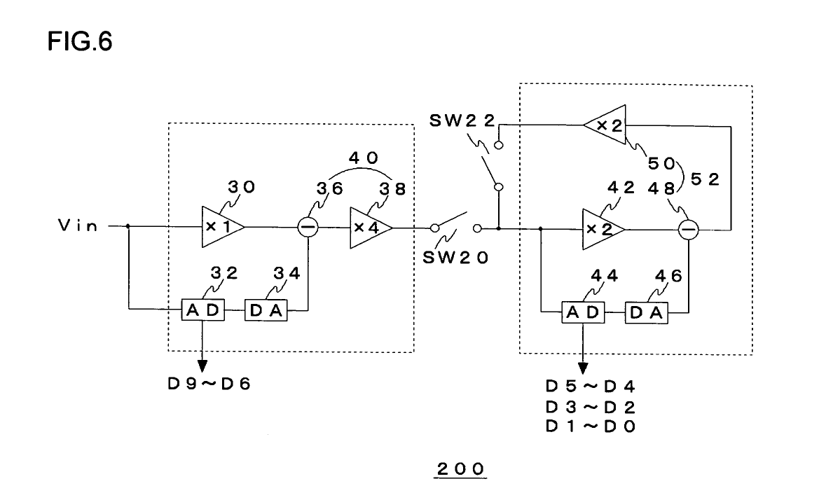

A description will now be provided regarding an AD converter 200 which incorporates the S&H circuit 100 in accordance with the aforementioned embodiment. FIG. 6 shows an exemplary configuration of the AD converter 200 which incorporates the S&H circuit 100. For one sampling, the AD converter 200 converts four bits in a non-cyclic-type upstream stage and six bits three times, two bits each time, in a cyclic-type downstream stage, thus delivering ten bits in total.

A description will first be given of the upstream stage of the AD converter 200. An input analog signal Vin is supplied to a first amplifier circuit 30 and a first AD conversion circuit 32. The first AD conversion circuit 32 is of a flash type with its resolution, i.e., the number of converted bits being four. The first AD conversion circuit 32 converts an input analog signal into a digital value and extracts the four higher-order bits to be delivered to an encoder (not shown) and a first DA conversion circuit 34. The first DA conversion circuit 34 converts the resulting digital value delivered by the first AD conversion circuit 32 into an analog value. The first amplifier circuit 30 samples the input analog signal, which is then held for a predetermined period of time and thereafter delivered to a first subtraction circuit 36. The first subtraction circuit 36 subtracts the output of the first DA conversion circuit 34 from the output of the first amplifier circuit 30.

A second amplifier circuit 38 amplifies the output of the first subtraction circuit 36 four times. Note that the first subtraction circuit 36 and the second amplifier circuit 38 may also be an integrated first subtraction amplifier circuit 40. This configuration can provide a simplified circuit.

The downstream stage will now be explained. An AD converter first switch SW20 and an AD converter second switch SW22 are alternately turned ON and OFF. In a condition where the AD converter first switch SW20 is in an ON state and the AD converter second switch SW22 is in an OFF state, an analog signal flowing from the upstream stage via the AD converter first switch SW20 is supplied to a third amplifier circuit 42 and a second AD conversion circuit 44. The second AD conversion circuit 44 is also of a flash type with its resolution, i.e., the number of converted bits being three including one redundant bit. The second AD conversion circuit 44 converts the input analog signal into a digital value, which is in turn delivered to an encoder (not shown) and a second DA conversion circuit 46. The second DA conversion circuit 46 converts the resulting digital value delivered by the second AD conversion circuit 44 into an analog value.

The third amplifier circuit 42 amplifies the input analog signal two times and delivers the resulting signal to a second subtraction circuit 48. The second subtraction circuit 48 subtracts the output of the second DA conversion circuit 46 from the output of the third amplifier circuit 42, and then delivers the resulting output to a fourth amplifier circuit 50. The second DA conversion circuit 46 provides an output that has been amplified substantially two times.

The fourth amplifier circuit 50 amplifies the output of the second subtraction circuit 48 two times. Note that the second subtraction circuit 48 and the fourth amplifier circuit 50 may also be an integrated second subtraction amplifier circuit 52. At this point, the AD converter first switch SW20 is in an OFF state and the AD converter second switch SW22 is in an ON state. The analog signal amplified in the fourth amplifier circuit 50 is fed back to the third amplifier circuit 42 and the second AD conversion circuit 44 via the AD converter second switch SW22. The aforementioned processing is subsequently repeated. In this instance, consider that the digital value of two bits excluding the redundant bit is delivered three times from the second AD conversion circuit 44. In this case, the downstream stage outputs six bits. Accordingly, the upstream stage and the downstream stage output a digital value of ten bits in total.

The S&H circuit 100 in accordance with the aforementioned embodiment can be added to the stage upstream of the input of the AD converter 200 described above. This configuration readily allows one AD converter to convert input analog signals of multiple channels into digital signals. Additionally, in the AD converter 200, at least the first subtraction amplifier circuit 40, the third amplifier circuit 42, and the second subtraction amplifier circuit 52 require a sample and hold operation for multiple inputs. It is thus possible to use the S&H circuit 100 according to the aforementioned embodiment. The S&H circuit 100 can also be used for the first amplifier circuit 30 or the comparator within the first AD conversion circuit 32 and the second AD conversion circuit 44.

As described above, the AD converter 200 in accordance with this embodiment employs the S&H circuit which uses a plurality of sampling capacitors and a common operational amplifier to perform time division sampling and holding, thereby making it possible to prevent degradation in signal accuracy while providing a reduced circuit footprint.

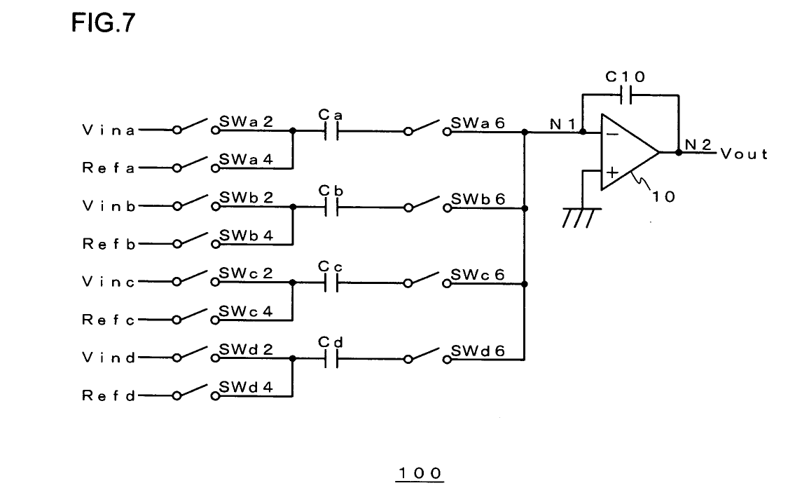

FIG. 7 is a view showing the configuration of an S&H circuit 100 in accordance with the second embodiment of the present invention. The S&H circuit 100 in accordance with the second embodiment has a simplified version of the structure of the S&H circuit 100 in accordance with the first embodiment. In FIG. 7, the components similar to those of the S&H circuit 100 according to the first embodiment are indicated with the same symbols and will not be explained again.

The S&H circuit 100 in accordance with the second embodiment does not include the external auto-zero voltage generation circuit 20 which is included in the S&H circuit 100 in accordance with the first embodiment. Accordingly, the S&H circuit 100 in accordance with the second embodiment does not include the Ach fourth switch SWa8, the Bch fourth switch SWb8, the Cch fourth switch SWc8, and the Dch fourth switch SWd8 which provide continuity or discontinuity to the path between the external auto-zero voltage generation circuit 20 and the sampling capacitors Ca to Cd of each channel. The S&H circuit 100 in accordance with the second embodiment, which does not include the external auto-zero voltage generation circuit 20, requires the operational amplifier 10 to apply an auto-zero voltage to the sampling capacitors Ca to Cd during a sampling period.

The S&H circuit 100 in accordance with the second embodiment operates basically in the same manner as the S&H circuit 100 in accordance with the first embodiment which has been described by way of example with reference to FIG. 5. The difference between these circuits will now be described. To begin with, the S&H circuit 100 in accordance with the second embodiment samples the input analog voltages Vina to Vind at the same time. During this sampling period, the first embodiment allows the Ach fourth switch SWa8, the Bch fourth switch SWb8, the Cch fourth switch SWc8, and the Dch fourth switch SWd8 to be turned ON to supply an auto-zero voltage from the external auto-zero voltage generation circuit 20 to the sampling capacitors Ca to Cd. Thus, the Ach third switch SWa6, the Bch third switch SWb6, the Cch third switch SWc6, and the Dch third switch SWd6 are in an OFF state. In this regard, the second embodiment allows the operational amplifier 10 to supply the auto-zero voltage, and thus, the Ach third switch SWa6, the Bch third switch SWb6, the Cch third switch SWc6, and the Dch third switch SWd6 are turned ON. The subsequent operation is the same as that of the first embodiment.

As described above, this embodiment employs the S&H circuit which uses a plurality of sampling capacitors and a common operational amplifier to perform time division sampling and holding. The S&H circuit shares the operational amplifier 10 as well as its feedback capacitor C10, thereby making it possible to achieve a reduction in circuit scale. When compared with the first embodiment, the external auto-zero voltage generation circuit 20 can be eliminated and the number of switches can be reduced, thereby providing a further reduction in the scale of the circuit. Although feedthrough noise is added to the node Na when the Ach third switch SWa6 is turned OFF, it is possible to draw the amount of charges corresponding to the feedthrough noise from the node Na when the Ach third switch SWa6 is subsequently turned ON. This holds true for the other channels. Accordingly, when a plurality of sampling capacitors and a common operational amplifier are used to perform time division sampling and holding, it is possible to reduce the effects of feedthrough noise, thereby preventing degradation in the accuracy of the sampling voltages.

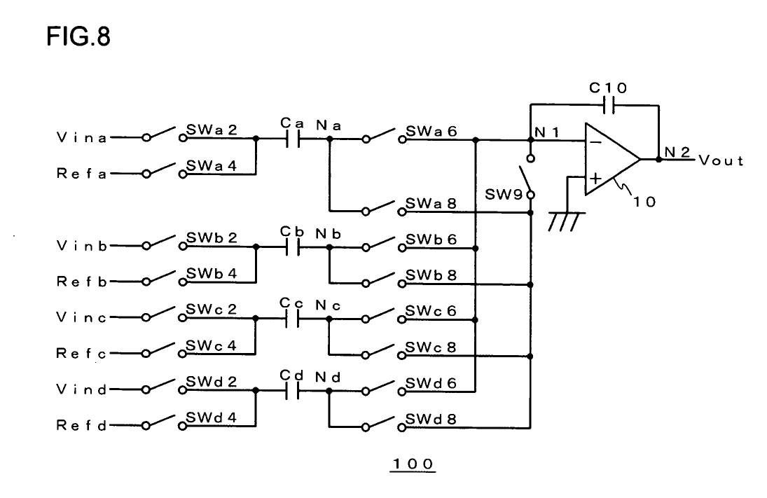

FIG. 8 is a view showing the configuration of an S&H circuit 100 in accordance with the third embodiment of the present invention. The S&H circuit 100 in accordance with the third embodiment is different from the S&H circuit 100 in accordance with the first embodiment in that the external auto-zero voltage generation circuit 20 is eliminated and a common switch SW9 is additionally included. In FIG. 8, the components similar to those of the S&H circuit 100 in accordance with the first embodiment are indicated with the same symbols and will not be explained again.

In the S&H circuit 100 in accordance with the third embodiment, the Ach fourth switch SWa8, the Bch fourth switch SWb8, the Cch fourth switch SWc8, and the Dch fourth switch SWd8 are not connected to the external auto-zero voltage generation circuit 20 but to the common switch SW9 instead. One end of the common switch SW9 is connected to the inverting input terminal of the operational amplifier 10. The other end thereof is connected in parallel to the Ach sampling capacitor Ca, the Bch sampling capacitor Cb, the Cch sampling capacitor Cc, and the Dch sampling capacitor Cd via the Ach fourth switch SWa8, the Bch fourth switch SWb8, the Cch fourth switch SWc8, and the Dch fourth switch SWd8.

The S&H circuit 100 in accordance with the third embodiment operates basically in the same manner as the S&H circuit 100 in accordance with the first embodiment which has been described by way of example with reference to FIG. 5. The difference between them will now be described. To begin with, the S&H circuit 100 in accordance with the third embodiment samples the input analog voltages Vina to Vind at the same time. During this sampling period, the first embodiment allows the Ach fourth switch SWa8, the Bch fourth switch SWb8, the Cch fourth switch SWc8, and the Dch fourth switch SWd8 to be turned ON to supply an auto-zero voltage from the external auto-zero voltage generation circuit 20 to the sampling capacitors Ca to Cd. In this regard, the third embodiment allows the operational amplifier 10 to supply the auto-zero voltage, and thus, those switches and the common switch SW9 are turned ON as well. Thereafter, when the sampling period ends and the period for amplification of the input analog voltage Vina of the A-channel starts, the Ach fourth switch SWa8, the Bch fourth switch SWb8, the Cch fourth switch SWc8, the Dch fourth switch SWd8, and the common switch SW9 are turned OFF. The subsequent operation is the same as that described in the first embodiment.

As described above, this embodiment employs the S&H circuit which uses a plurality of sampling capacitors and a common operational amplifier to perform time division sampling and holding. The S&H circuit shares the operational amplifier 10 as well as its feedback capacitor C10, thereby making it possible to achieve a reduction in circuit scale. When the third embodiment is compared with the first embodiment, it should be noted that the external auto-zero voltage generation circuit 20 does not need to be included, thereby making it possible to provide a further reduction in circuit scale. When the Ach fourth switch SWa8 is turned OFF, feedthrough noise is added to the node Na. In this regard, the Ach third switch SWa6 and the Ach fourth switch SWa8 may be made substantially equal in size. This allows for the drawing of the amount of charges corresponding to the feedthrough noise from the node Na when the Ach third switch SWa6 is subsequently turned ON. In other words, the Ach third switch SWa6 has absorbed the feedthrough noise. This holds true for the other channels. Accordingly, when a plurality of sampling capacitors and a common operational amplifier are used to perform time division sampling and holding, it is possible to reduce the effects of feedthrough noise, thereby preventing degradation in the accuracy of the sampling voltages.

In the foregoing, the present invention has been described in accordance with the embodiments. These embodiments have been illustrated by way of example only, and thus it should be appreciated that various modifications may be made to each of the components and combinations of each of the process steps. It will be also understood by those skilled in the art that those modifications will also fall within the scope of the present invention.

For example, with reference to the timing chart of FIG. 5, an example has been described in which the Ach fourth switch SWa8, the Bch fourth switch SWb8, the Cch fourth switch SWc8, and the Dch fourth switch SWd8 are turned OFF at the same time for all four channels. It should be noted that to adjust the OFF timing for each channel as required, the external auto-zero voltage generation circuit 20 needs to be driven into a standby mode in synchronization with the timing. This would allow for the provision of very fine adjustments.

Furthermore, in the aforementioned embodiments, an example has been described in which the external auto-zero voltage generation circuit 20 is kept in a standby mode for a period of time during which the Ach first switch SWa2, the Bch first switch SWb2, the Cch first switch SWc2, and the Dch first switch SWd2 are turned OFF and then turned ON. It should be noted that, without being limited to this example, the external auto-zero voltage generation circuit 20 can be driven into a standby mode with an optimum timing in a circuit to which the invention is applicable.

For example, the timing of transition to a standby mode may be varied for each channel. Since connections to the operational amplifier 10 are made in each channel with different timings, simultaneous driving of the external auto-zero voltage generation circuit 20 into a standby mode would cause one end of the Ach sampling capacitor Ca, the Bch sampling capacitor Cb, the Cch sampling capacitor Cc, and the Dch sampling capacitor Cd to be connected to the operational amplifier 10 in different (although short) periods of time in a standby mode of the external auto-zero voltage generation circuit 20. When such connections result in an adverse effect on the sampling and holding operation, the timing with which the external auto-zero voltage generation circuit 20 is transitioned into a standby mode is adjusted for each channel so that the periods of time during which the connections are made to the operational amplifier 10 in a standby mode of the external auto-zero voltage generation circuit 20 coincide with each other. It should be noted that a plurality of external auto-zero voltage generation circuits 20 have to be prepared in order to provide this type of control.

Additionally, the timing for recovery from a standby mode may be provided before the Ach first switch SWa2, the Bch first switch SWb2, the Cch first switch SWc2, and the Dch first switch SWd2 are turned ON. Changing the external auto-zero voltage generation circuit 20 from a standby mode to an operating mode immediately before the Ach first switch SWa2, the Bch first switch SWb2, the Cch first switch SWc2, and the Dch first switch SWd2 are turned ON may cause a desired voltage value not to be obtained instantly. In this regard, the external auto-zero voltage generation circuit 20 can be placed in the operating mode beforehand, thereby allowing a desired voltage value to be obtained immediately after the Ach first switch SWa2, the Bch first switch SWb2, the Cch first switch SWc2, and the Dch first switch SWd2 have been turned ON.

Further to this, the S&H circuit 100 in accordance with the embodiments is applicable to various circuits such as comparators, low-pass filters, and peak value detection circuits, without being limited to the AD converter 200.

What is claimed is:

1. A sample and hold circuit comprising:
one operational amplifier;
one feed back capacitor located in a feedback path connecting an input terminal and an output terminal of the operational amplifier;
a plurality of sampling capacitors which sample input analog signals of multiple channels on each channel; and
switches which selectively supply voltages sampled at one terminal of the plurality of sampling capacitors from the other terminal to the operational amplifier, the switches corresponding in number to the capacitors, wherein
the switches are selectively turned ON, thereby performing time division sampling and holding.

2. A sample and hold circuit comprising:
one operational amplifier;
a plurality of sampling capacitors which sample input analog signals of multiple channels on each channel;
first switches which selectively supply voltages sampled at one terminal of the plurality of sampling capacitors from the other terminal to the operational amplifier, the first switches corresponding in number to the capacitors; and
an auto-zero voltage generation circuit which applies a voltage to the other terminal of a sampling capacitor during a sampling period, the voltage corresponding to an input node voltage of the operational amplifier in an auto-zero state, wherein
the sample and hold circuit selectively turns ON the first switches, thereby performing time division sampling and holding.

3. The sample and hold circuit according to claim 2, further comprising second switches which correspond in number to the sampling capacitors, the second switches being provided between the other terminals of the sampling capacitors and the auto-zero voltage generation circuit, and wherein
the size of the first switches and the size of the second switches correspond to each other on each channel.

4. The sample and hold circuit according to claim 3, wherein the auto-zero voltage generation circuit is controlled in a standby mode, as appropriate, within a period of time during which all the first switches are turned OFF and then turned ON.

5. The sample and hold circuit according to claim 3, wherein the auto-zero voltage generation circuit is controlled in a standby mode or power saving mode at least during part of a period of time in which all the second switches are in an OFF state.

6. The sample and hold circuit according to claim 2, wherein the auto-zero voltage generation circuit is a dedicated circuit which generates an auto-zero voltage.

7. The sample and hold circuit according to claim 3, wherein the auto-zero voltage generation circuit is a dedicated circuit which generates an auto-zero voltage.

8. The sample and hold circuit according to claim 2, wherein the auto-zero voltage generation circuit is a self-bias voltage generation circuit in the operational amplifier.

9. The sample and hold circuit according to claim 3, wherein the auto-zero voltage generation circuit is a self-bias voltage generation circuit in the operational amplifier.

10. The sample and hold circuit according to claim 2, wherein the auto-zero voltage generation circuit is a self-bias voltage generation circuit in another operational amplifier which is different from the operational amplifier.

11. The sample and hold circuit according to claim 3, wherein the auto-zero voltage generation circuit is a self-bias voltage generation circuit in another operational amplifier which is different from the operational amplifier.

12. An analog-digital converter which converts an input analog signal to a digital signal, comprising the sample and hold circuit according to claim 1, wherein the sample and hold circuit samples the input analog signal.
